(19) United States
(12) Patent Application Publication
(10) Pub. No.: US 2006/0211240 A1
(43) Pub. Date: Sep. 21, 2006

(54) Method of enhancing adhesion between dielectric layers

(75) Inventors: Chung Chi, Tainan (TW); Tien-I Bao, Hsin-Chu (TW); Syun-Ming Jang, Hsin-Chu (TW); Shou-Yi Chang, Hsin-Chu (TW)

Correspondence Address: TUNG & ASSOCIATES, Suite 120, 838 W. Long Lake Road, Bloomfield Hills, MI, 48302, US

(73) Assignee: Taiwan Semiconductor Manufacturing Co., Ltd.

(21) Appl. No.: 11/084,494

(22) Filed: Mar. 18, 2005

(51) Int. Cl. H01L 21/4763; H01L 21/31

(52) U.S. Cl. 438/644; 438/790; 438/789

(57) ABSTRACT

A method for enhancing adhesion between adjacent dielectric layers, particularly in the formation of trenches and vias in the layers during the fabrication of semiconductor integrated circuits on wafer substrates. The method may include providing a via dielectric layer on a substrate above a metal conductive layer in the substrate, providing an adhesive layer on the via dielectric layer, providing a trench dielectric layer on the adhesive layer, etching a via in the via dielectric layer, etching a trench in the trench dielectric layer, filling the via and trench with a metal filling layer, and planarizing the filling layer. The adhesive layer between the via dielectric layer and the trench dielectric layer prevents CMP-induced peeling during the planarization step, and cracking of the layers during the package step.

### FIELD OF THE INVENTION

The present invention relates to formation of trenches and vias in dielectric layers in the fabrication of semiconductor integrated circuits on wafer substrates. More particularly, the present invention relates to a method of enhancing adhesion between dielectric layers having a low dielectric constant.

### BACKGROUND OF THE INVENTION

The fabrication of various solid state devices requires the use of planar substrates, or semiconductor wafers, on which integrated circuits are fabricated. The final number, or yield, of functional integrated circuits on a wafer at the end of the IC fabrication process is of utmost importance to semiconductor manufacturers, and increasing the yield of circuits on the wafer is the main goal of semiconductor fabrication. After packaging, the circuits on the wafers are tested, wherein non-functional dies are marked using an inking process and the functional dies on the wafer are separated and sold. IC fabricators increase the yield of dies on a wafer by exploiting economies of scale. Over 1000 dies may be formed on a single wafer which measures from six to twelve inches in diameter.

Various processing steps are used to fabricate integrated circuits on a semiconductor wafer. These steps include deposition of a conducting layer on the silicon wafer substrate; formation of a photoresist or other mask such as titanium oxide or silicon oxide, in the form of the desired metal interconnection pattern, using standard lithographic or photolithographic techniques; subjecting the wafer substrate to a dry etching process to remove the conducting layer from the areas not covered by the mask, thereby etching the conducting layer in the form of the masked pattern on the substrate; removing or stripping the mask layer from the substrate typically using reactive plasma and chlorine gas, thereby exposing the top surface of the conductive interconnect layer; and cooling and drying the wafer substrate by applying water and nitrogen gas to the wafer substrate.

The numerous processing steps outlined above are used to cumulatively apply multiple electrically conductive and insulative layers on the wafer and pattern the layers to form the circuits. The final yield of functional circuits on the wafer depends on proper application of each layer during the process steps. Proper application of those layers depends, in turn, on coating the material in a uniform spread over the surface of the wafer in an economical and efficient manner.

In the semiconductor industry, copper is being increasingly used as the interconnect material for microchip fabrication. The conventional method of depositing a metal conducting layer and then etching the layer in the pattern of the desired metal line interconnects and vias cannot be used with copper because copper is not suitable for dry-etching. Special considerations must also be undertaken in order to prevent diffusion of copper into silicon during processing. Therefore, the dual-damascene process has been developed and is widely used to form copper metal line interconnects and vias in semiconductor technology. In the dual-damascene process, the dielectric layer rather than the metal layer is etched to form trenches and vias, after which the metal is deposited into the trenches and vias to form the desired interconnects. Finally, the deposited copper is subjected to chemical mechanical planarization (CMP) to remove excess copper (copper overburden) extending from the trenches.

A typical dual damascene process is shown in the cross-sectional views of FIGS. 1A-1D. The process is carried out on a substrate 100 on which a conductive metal layer 102 is deposited. A dielectric layer 104, an etch stop layer 106 and a dielectric layer 108 are sequentially formed on the substrate 100. A photoresist layer 110 is then formed over the dielectric layer 108. Photolithography techniques are then used to pattern the photoresist layer 110 for subsequent formation of a via opening in the photoresist layer 110.

The photoresist layer 110 is used as an etching mask as the dielectric layer 108, the etch stop layer 106 and the dielectric layer 104 are sequentially etched to form a via opening 112 through which the metal layer 102 is exposed, as shown in FIG. 1B. The photoresist layer 110 is removed and a second photoresist layer 114 is formed on the substrate 100. Photolithography techniques are then used to pattern the photoresist layer 114 for formation of a trench above the via opening 112.

The photoresist layer 114 is used as an etching mask and the etch stop layer 108 as an etch stop as the dielectric layer 108 is etched to form a trench 116 over the via opening 112, as shown in FIG. 1C. The photoresist 114 is subsequently removed. Finally, as shown in FIG. 1D, a metallic layer 118 is deposited into the via opening 112 and overlying trench 116. Finally, the metallic layer 118 is subjected to chemical mechanical planarization (CMP) for the purpose of planarizing or smoothing the upper surface of the metallic layer 118.

Over the past 20 years, the density of integrated circuits (ICs) fabricated on semiconductor wafer substrates has doubled about every 18 months. When the gate length of ICs is less than about 0.18 □m, the propagation time or delay time is determined by interconnect delay rather than device gate delay. To address this problem, new materials with low dielectric constants (k) are being developed for use as dielectric layers in IC fabrication. The aim of this development effort is to reduce time constant (RC delay), power consumption and cross-talk in ICs. This development effort increases in importance as the gate length of ICs approaches 0.09 □m and beyond.

There are two basic groups of low-k dielectric materials: the traditional inorganic group, which includes silicon dioxide; and the newer group of organic polymers, which includes poly-para-xylene. Organic polymers are considered an improvement over inorganic low-k dielectric materials because the dielectric constant of organic polymers can be as low as 2.0. However, most of the currently-available organic polymers suffer from several disadvantages, including insufficient thermal stability and fragility.

While it is well-suited for planarization if the correct slurry and process parameters are used, CMP may induce physical stresses in the substrate, leading to cracking and peeling of adjacent dielectric layers particularly at the interface of the layers. Moreover, due to the increasingly widespread usage of fragile low-k dielectric materials, CMP may result in shearing or crushing of these layers. Accordingly, a new technique is needed for providing enhanced adhesion between adjacent low-k dielectric layers for the formation of trenches and vias in the respective layers, in order to prevent or minimize cracking, peeling or other CMP-induced stresses imparted to the dielectric layers during planarization of the metal layer filling the trenches and vias formed in the layers.

An object of the present invention is to provide a novel method which is suitable for enhancing adhesion between adjacent dielectric layers.

Another object of the present invention is to provide a novel method which may be used to prevent cracking or peeling of dielectric layers deposited on a substrate during chemical mechanical planarization.

Still another object of the present invention is to provide a novel method suitable for enhancing the structural integrity of trenches and vias formed in dielectric layers on a substrate.

Yet another object of the present invention is to provide a novel method which is suitable for enhancing inter-layer adhesion of dielectric layers having a low dielectric constant to prevent stress-induced peeling or cracking of the layers during processing.

A still further object of the present invention is to provide a novel method which is suitable for enhancing the inter-layer structural integrity between adjacent porous dielectric layers having a low dielectric constant.

Another object of the present invention is to provide a novel method which is suitable for enhancing inter-layer adhesion of dielectric layers having a medium or high dielectric constant.

Another object of the present invention is to provide a novel method which may be used as part of a dual-damascene process or alternative process for the formation of vias and trenches in dielectric layers.

### SUMMARY OF THE INVENTION

These and other objects and advantages of the present invention are provided in a novel method for enhancing adhesion between adjacent dielectric layers, particularly in the formation of trenches and vias in the layers during the fabrication of semiconductor integrated circuits on wafer substrates. The method may include providing a via dielectric layer on a substrate above a metal conductive layer in the substrate, providing an adhesive layer on the via dielectric layer, providing a trench dielectric layer on the adhesive layer, etching a via in the via dielectric layer, etching a trench in the trench dielectric layer, filling the via and trench with a metal filling layer, and planarizing the filling layer. The adhesive layer between the via dielectric layer and the trench dielectric layer prevents CMP-induced peeling and cracking of the layers during the planarization step.

In a preferred embodiment, the precursor for the adhesive layer is the low-k dielectric organic OMCTS (octamethylcyclotetrasiloxane). Other suitable precursors for the adhesive layer include trimethysilane(TMS) and the siloxane compounds hexamethylcyclotrisiloxane, decamethylcyclopentasiloxane, dodecamethylcyclohexasiloxane, and HMDS (hexamethyldisiloxane).

### BRIEF DESCRIPTION OF THE DRAWINGS

The invention will now be described, by way of example, with reference to the accompanying drawings, in which:

FIG. 1A is a cross-sectional view illustrating sequential formation of adjacent, bottom and top dielectric layers on a substrate according to conventional techniques;

FIG. 1B is a cross-sectional view illustrating formation of a via in the bottom dielectric layer of FIG. 1A according to conventional techniques;

FIG. 1C is a cross-sectional view illustrating formation of a trench in the top dielectric layer according to conventional techniques;

FIG. 1D is a cross-sectional view illustrating filling of the via and trench with a metal filling layer according to conventional techniques;

FIG. 2A is a cross-sectional view illustrating sequential formation of a via dielectric layer on a substrate and an adhesion layer on the via dielectric layer in a first process step according to the present invention;

FIG. 2B is a cross-sectional view illustrating sequential formation of a trench dielectric layer on the adhesive layer and a patterned via photoresist layer on the trench dielectric layer in a third process step;

FIG. 2C is a cross-sectional view illustrating formation of a via in the via dielectric layer and a patterned trench photoresist layer on the trench dielectric layer in a fourth process step;

FIG. 2D is a cross-sectional view illustrating formation of a trench in the trench dielectric layer in a fifth process step;

FIG. 2E is a cross-sectional view illustrating filling of the via and trench with a copper filling layer in a sixth process step;

FIG. 2F is a cross-sectional view illustrating planarization of the copper filling layer;

FIG. 3 is a cross-sectional view of the invention; and

FIG. 4 is a flow diagram summarizing a typical process flow for implementation of the present invention.

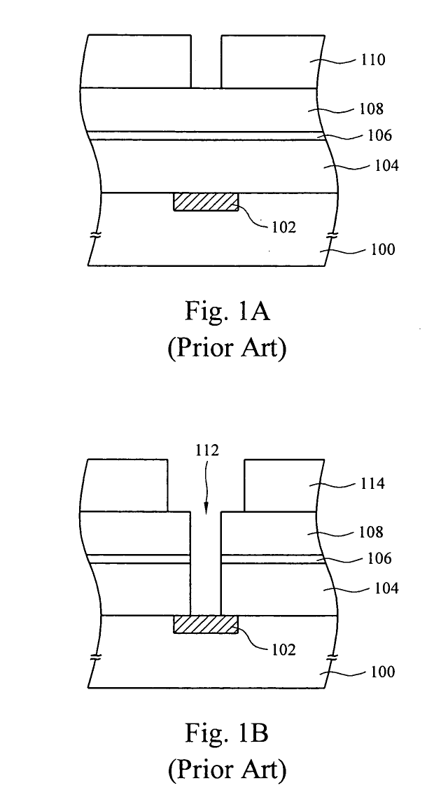

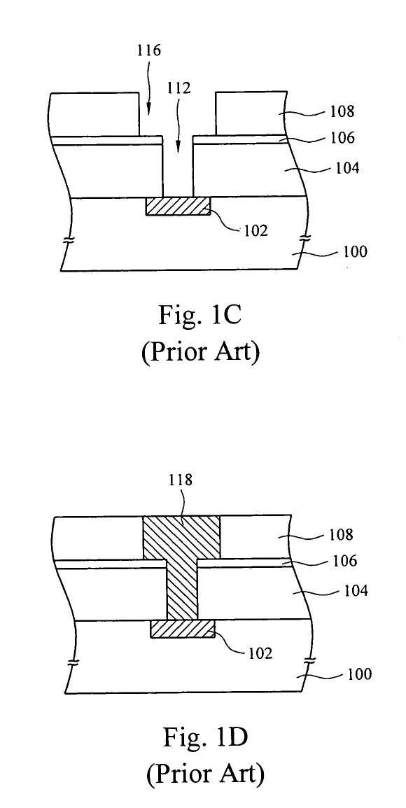

### DESCRIPTION OF THE PREFERRED EMBODIMENTS

The present invention has particularly beneficial utility in the adhesion of adjacent low-k dielectric layers to each other for the fabrication of trenches and vias in the layers in order to reinforce the layers during chemical mechanical planarization (CMP). However, the invention may be more generally applicable to facilitating adhesion of adjacent dielectric layers of various description to each other in a variety of applications involving semiconductor processing, as well as in other industrial applications.

The present invention is generally directed to a novel method for enhancing adhesion between adjacent dielectric layers in the formation of trenches and vias in the layers and deposition of metal filling in the trenches and vias during the course of fabricating semiconductor integrated circuits on wafer substrates. According to a preferred embodiment, the method includes deposition of a via dielectric layer on a substrate above a metal conductive layer in the substrate, which via dielectric layer will subsequently be etched to define a via opening therein; deposition of an adhesive layer on the via dielectric layer; deposition of a trench dielectric layer on the adhesive layer, which trench dielectric layer will subsequently be etched to define a trench opening therein, above the via; etching of the via opening in the via dielectric layer; etching of the trench opening in the trench dielectric layer; filling of the via opening and trench opening with a metal filling layer; and planarizing the filling layer. The adhesive layer between the via dielectric layer and the trench dielectric layer prevents CMP-induced peeling and cracking of the layers, particularly at the interface therebetween, during the planarization step, and cracking of the layer during the packaging step. While the method may be used as a part of a dual damascene process for the fabrication of trenches and vias on a substrate, the invention is not limited to such dual damascene process and may be utilized in any application in which a first dielectric layer is to be deposited on a second dielectric layer such as in the formation of connected vias and trenches.

In a preferred embodiment, the adhesive layer is synthesized from adhesive layer-forming materials such as the low-k dielectric siloxane precursor OMCTS (octamethylcyclotetrasiloxane) only. Other suitable siloxane precursors for the adhesive layer include the siloxane compounds hexamethylcyclotrisiloxane, decamethylcyclopentasiloxane, dodecamethylcyclohexasiloxane, and HMDS (hexamethyldisiloxane).

In a most preferred embodiment, the adhesive layer-forming material is deposited using a plasma enhanced chemical vapor deposition (PECVD) process. The carrier gas for the siloxane precursor may be He, CO₂, CO, N₂ or any suitable inert gas. During formation of the adhesive layer, the oxidant gas is omitted from the carrier gas. Typical process parameters for the PECVD deposition process are as shown in Table I below.

TABLE I

| | | |
|---|---|---|
| Parameter | Value | Range |

| | | | | |
|---|---|---|---|---|
| Adhesive precursor flow | 5 | ml/min. | 0.5-10 | ml/min. |
| Carrier gas flow | 2500 | sccm | 500-5000 | sccm |
| (oxidant gas omitted) | | | | |
| Dep. Pressure | 5 | Torr | 0.2-10 | Torr |
| Dep. Temp | 400 | C. | 100-500 | C. |
| HF RF power | 1500 | W | 150-2000 | W |
| LF RF power | 250 | W | 0.500 | W |

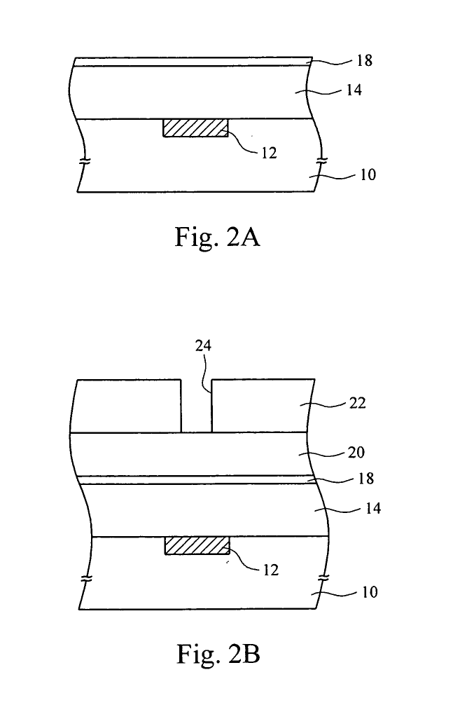

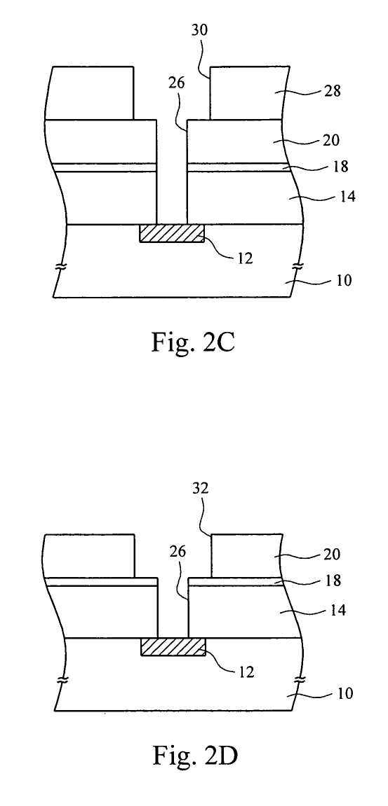

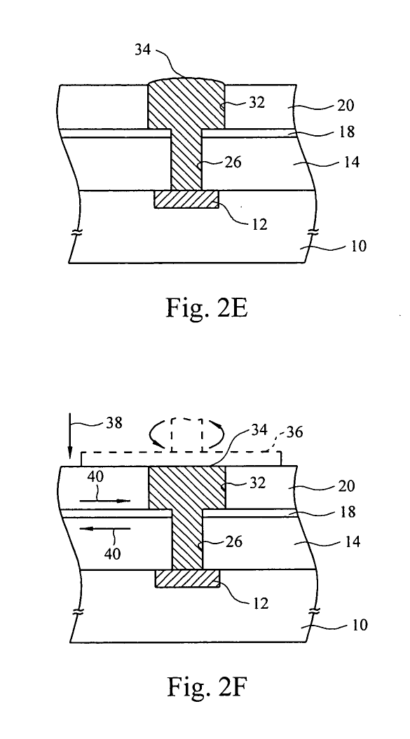

Referring to FIGS. 2A-2F, cross-sectional views illustrating a typical sequence of process steps in implementation of the present invention are shown. As shown in FIG. 2A, the process of the present invention is carried out on a substrate 10 on which a conductive metal layer 12, such as copper, is deposited. A via dielectric layer 14 is deposited on the conductive metal layer 12, typically using conventional high-density plasma chemical vapor deposition (HDPCVD) techniques. The via dielectric layer 14 is typically a porous dielectric material with a low dielectric constant (k), including but not limited to such materials as fluorinated tetraethoxysilane (FTEOS), hydrogen silsesquioxane (HSQ), benzocyclobutene (BCB), TMOS (tetramethoxysilane), HMDS (hexamethyldisiloxane), SOB (trimethylsilil borxle), DADBS (diaceloxyditerliarybutoxsilane) and SOP (trimethylsilil phosphate), having dielectric constants below 3.9. The dielectric layer-forming material is introduced into the HDPCVD chamber with an oxidant gas.

As shown in FIG. 2A, according to the present invention an adhesive layer 18 is deposited on the via dielectric layer 14 typically using a plasma enhanced chemical vapor deposition (PECVD) process. The process is carried out typically using the process parameters listed in table I above; however, it will be recognized by those skilled in the art that the invention may be carried out using process parameters which vary from those set forth in Table I. In a preferred embodiment, the adhesive layer 18 has a thickness of typically about 50˜150 angstroms.

As shown in FIG. 2B, a trench dielectric layer 20, typically a porous material with a low dielectric constant (k) such as that of the via dielectric layer 14, is deposited on the adhesive layer 18. A via photoresist layer 22 is then formed over the trench dielectric layer 20. The via photoresist layer 22 is patterned using conventional photolithography techniques to provide photoresist openings 24, each corresponding in position to a via opening 26 (FIG. 2C) to be subsequently etched through the trench dielectric layer 20, the adhesive layer 18 and the via dielectric layer 14, respectively.

As shown in FIG. 2C, the via photoresist layer 22 shown in FIG. 2B is used as an etching mask as the trench dielectric layer 20, the adhesive layer 18 and the via dielectric layer 14 are sequentially etched to form a via opening 26 through which the metal layer 12 is exposed. The via photoresist layer 22 of FIG. 2B is then stripped from the trench dielectric layer 20, after which a patterned trench photoresist layer 28 is formed on the trench dielectric layer 20. Photolithography techniques are then used to pattern photoresist openings 30 in the trench photoresist layer 28 for formation of a trench opening above each via opening 26.

As shown in FIG. 2D, the trench photoresist layer 28 shown in FIG. 2C is used as an etching mask as the trench dielectric layer 20 is etched to form a trench opening 32 over and in communication with the via opening 26, as shown in FIG. 2D. The trench photoresist layer 28 of FIG. 2C is subsequently stripped from the trench dielectric layer 20. As shown in FIG. 2E, a metallic filling layer 34, typically copper, is deposited into the via opening 26 and the overlying trench opening 32. Finally, as shown in FIG. 2F, the metallic layer 34 is subjected to chemical mechanical planarization (CMP) for the purpose of planarizing or smoothing the upper surface of the metallic layer 34, as is known by those skilled in the art.

As further shown in FIG. 2F, the CMP process for planarization of the metal filling layer 34 involves pressing of a CMP polishing pad 36 against the surface of the metal filling layer 34 with a downward force 38 as the polishing pad 36 is moved in a rotating or linear manner. This causes shear pressure 40 to be exerted on the trench dielectric layer 20 and the via dielectric layer 14. Accordingly, the adhesive layer 18 is effective in preventing or minimizing cracking and/or peeling of the trench dielectric layer 20 and the via dielectric layer 14 throughout the CMP and subsequent IC fabrication processes.

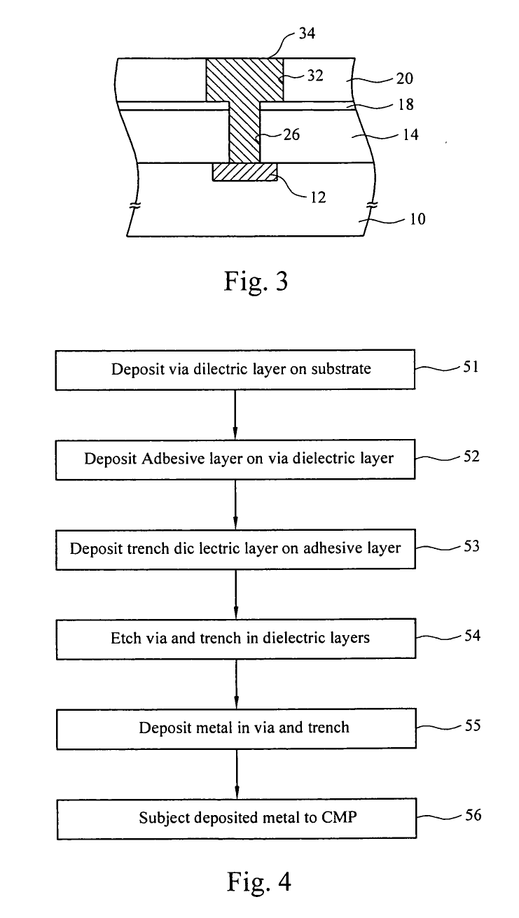

Referring next to FIG. 3, the trench dielectric layer 20 and the via dielectric layer 14 are directly bonded to each other through the adhesive layer 18, as heretofore described. Accordingly, the adhesive layer 18 is effective in preventing or minimizing cracking and/or peeling of the trench dielectric layer 20 and the via dielectric layer 14, particularly at the interface between the via dielectric layer 14 and the adhesive layer 18 and the interface between the trench dielectric layer 20 and the adhesive layer 18, throughout the CMP and subsequent IC fabrication processes.

A typical process flow of the method of the present invention is summarized in the flow diagram in FIG. 4. In process step S1, a via dielectric layer is deposited on a metal layer previously provided on a substrate. In process step S2, an adhesive layer is deposited on the via dielectric layer. In process step S3, a trench dielectric layer is deposited on the adhesive layer. In process step S4, a via is etched in the via dielectric layer and a trench is etched in the trench dielectric layer. In process step S5, a metal filling layer is deposited in the via and the trench. In process step S6, the metal filling layer is subjected to chemical mechanical planarization, wherein the adhesive layer enhances the structural integrity between the dielectric layers to prevent or minimize cracking and/or peeling of the layers.

While the preferred embodiments of the invention have been described above, it will be recognized and understood that various modifications can be made in the invention and the appended claims are intended to cover all such modifications which may fall within the spirit and scope of the invention.

What is claimed is:

1. A method of enhancing adhesion between a first dielectric layer and a second dielectric layer, comprising the step of:
forming a first dielectric layer using a dielectric layer-forming material and an oxidant;
forming an adhesive layer on said first dielectric layer using an adhesive layer-forming material without an oxidant; and
forming a second dielectric layer on said adhesive layer.

2. The method of claim 1 wherein said adhesive layer is formed using a siloxane precursor.

3. The method of claim 1 further comprising the steps of providing a via opening in said first dielectric layer and a trench opening in said second dielectric layer and providing a metal filling layer in said via opening and said trench opening.

4. The method of claim 3 wherein said adhesive layer is formed using a siloxane precursor.

5. The method of claim 1 wherein said first dielectric layer and said second dielectric layer each comprises a substantially porous material having a dielectric constant of below about 3.9.

6. The method of claim 5 wherein said adhesive layer is formed using a siloxane precursor.

7. The method of claim 5 further comprising the steps of providing a via opening in said first dielectric layer and a trench opening in said second dielectric layer and providing a metal filling layer in said via opening and said trench opening.

8. The method of claim 7 wherein said adhesive layer is formed using a siloxane precursor.

9. The method of claim 2 wherein said siloxane precursor is a siloxane selected from the group consisting of octamethylcyclotetrasiloxane, hexamethylcyclotrisiloxane, decamethylcyclopentasiloxane, dodecamethylcyclohexasiloxane and hexamethyldisiloxane.

10. The method of claim 9 further comprising the steps of providing a via opening in said first dielectric layer and a trench opening in said second dielectric layer and providing a metal filling layer in said via opening and said trench opening.

11. The method of claim 9 wherein said first dielectric layer and said second dielectric layer each comprises a substantially porous material having a dielectric constant of below about 3.9.

12. The method of claim 11 further comprising the steps of providing a via opening in said first dielectric layer and a trench opening in said second dielectric layer and providing a metal filling layer in said via opening and said trench opening.

13. A method of enhancing adhesion of a first dielectric layer to a second dielectric layer, comprising the step of:
forming a first dielectric layer using a siloxane precursor and an oxidant;
providing an adhesive layer on said first dielectric layer using a siloxane precursor without an oxidant; and
providing a second dielectric layer on said adhesive layer.

14. The method of claim 13 further comprising the steps of providing a via opening in said first dielectric layer and a trench opening in said second dielectric layer and providing a metal filling layer in said via opening and said trench opening.

15. The method of claim 13 wherein said first dielectric layer and said second dielectric layer each comprises a substantially porous material having a dielectric constant of below about 3.9.

16. The method of claim 15 further comprising the steps of providing a via opening in said first dielectric layer and a trench opening in said second dielectric layer and providing a metal filling layer in said via opening and said trench opening.

17. A method of enhancing adhesion between a first dielectric layer and a second dielectric layer, comprising the steps of:
forming a first dielectric layer using a siloxane precursor and an oxidant;
providing an adhesive layer on said first dielectric layer using a siloxane precursor without an oxidant;
providing a second dielectric layer on said adhesive layer;
providing a via opening in said first dielectric layer;
providing a trench opening in said second dielectric layer and said adhesive layer; and
providing a metal filling layer in said via opening and said trench opening.

18. The method of claim 17 wherein said adhesive layer is formed using a siloxane precursor.

19. The method of claim 17 wherein said first dielectric layer and said second dielectric layer each comprises a substantially porous material having a dielectric constant of below about 3.9.

20. The method of claim 19 wherein said adhesive layer is formed using a siloxane precursor.
